(19) United States
(12) Patent Application Publication
(10) Pub. No.: US 2026/0107696 A1
(43) Pub. Date: Apr. 16, 2026

(54) Microwave Surface Waves in Layered Superconductor-Dielectric Nanostructures

(71) Applicant: Abu Dhabi University, Abu Dhabi (AE)

(72) Inventor: Montasir Yousof Abdallah Qasymeh, Abu Dhabi (AE)

(73) Assignee: Abu Dhabi University, Abu Dhabi (AE)

(21) Appl. No.: 18/912,958

(22) Filed: Oct. 11, 2024

(51) Int. Cl. H10N 60/82; B82Y 10/00; H10N 60/83

(52) U.S. Cl. CPC H10N 60/82; B82Y 10/00; H10N 60/83

(57) ABSTRACT

A superconductor-dielectric-superconductor including a first superconductor layer; a dielectric layer, and a second superconductor layer. Surface waves, in a microwave frequency range, propagate along the interface between dielectric and superconducting layers. The surface waves are hybrid waves composed of electromagnetic fields and supercurrent vortices.

### BACKGROUND

Electromagnetic surface waves, for instance, can propagate in layered media and have critical applications in telecommunications and electronics. Surface plasmon polaritons (SPPs) are a notable example, enabling the confinement of electromagnetic waves significantly below the diffraction limit. Mechanical surface waves, on the other hand, operate in a different paradigm and have applications in seismology, non-destructive testing, and more.

Recently, a hybrid surface wave at microwave frequencies in a layered superconductor-dielectric nanostructure has been discovered. This wave exhibits a unique combination of electromagnetic fields and super-current vortices on the dielectric and superconducting sides of the interface, respectively. On the dielectric side, the electromagnetic fields satisfy Maxwell's equations, while on the superconducting side, the super-current vortices are governed by Ampere's and London's equations. Currently, there is no device that can take advantage of this hybrid surface wave.

### BRIEF DESCRIPTION OF DRAWINGS

FIG. 1 is a diagram of example interface;

FIG. 2 is a diagram of an example superconductor dielectric nanostructure;

FIG. 3 is a diagram of an example graph;

FIG. 4 is a diagram of an example graph;

FIG. 5 is a networking environment; and

FIG. 6 is a diagram of a computer.

### DETAILED DESCRIPTION OF PREFERRED EMBODIMENTS

The following detailed description refers to the accompanying drawings. The same reference numbers in different drawings may identify the same or similar elements.

Systems, devices, and/or methods described herein are for superconducting device that can use surface waves at microwave frequencies. In embodiments, a hybrid surface wave at microwave frequencies may occur in a layered superconductor-dielectric nanostructure. This wave exhibits a unique combination of electromagnetic fields and super-current vortices on the dielectric and superconducting sides of the interface, respectively. On the dielectric side, the electromagnetic fields satisfy Maxwell's equations, while on the superconducting side, the super-current vortices are governed by Ampere's and London's equations. In embodiments, the superconductor device described herein may use these surface waves at microwave frequencies. In embodiments, the superconductor device described herein can be downscaled below the diffraction limit, achieving a new level of scalability for superconducting quantum devices.

Existing in various physical forms, surface waves have distinct applications. For example, electromagnetic surface waves play a crucial role in wireless communication, while mechanical surface waves have significant applications in ocean engineering and sonar sensing. The confinement of the electromagnetic (EM) waves is normally limited by diffraction. For example, the cross-sectional dimensions of microwave waveguides or optical fibers must be larger than half the wavelength of the guided wave. However, various techniques have been developed to tightly confine EM waves significantly below the diffraction limit. In the terahertz frequency range, a prominent example is the surface plasmon polariton (SPP) waves. Other examples include nanostructured optical microfibers, and silicon-on-oxide waveguides. In the microwave frequency range, SPP waves are naturally non-existing. This is due to the metals' inability to support internal plasmonic oscillations at microwave frequency, a metallic microstructure that incorporates a pattern of slender wires has been shown to be capable of supporting surface plasmon polariton (SPP) waves at GHz microwave frequencies. Furthermore, structured metal surfaces, perforated with holes, have been demonstrated to support SPP modes extending into microwave frequencies. This is achieved through careful design of the holes and geometric parameters, resulting in what are known as spoof surface plasmon polaritons. In another study, conformal surface plasmons are reported for SPP waves propagating on ultrathin and flexible films with subwavelength widths in the microwave frequency range. Building on these concepts, a variety of plasmonic-based structures operating at microwave frequencies have been developed and experimentally confirmed in recent years. Generally, the size of these structures is in the millimeter range. While dissipation can be minimized for optimum geometric parameters, losses remain a significant limitation in practical device design.

Superconductors, on the other hand, exhibit zero electrical resistance, and magnetic fields can penetrate them only to limited depths. This penetration is characterized by the London penetration depth, denoted as λ, which spans up to a few nanometers in most superconducting materials. Superconductivity can be explained by various theories, including the BCS (Bardeen-Cooper-Schrieffer) theory and the Ginzburg-Landau theory. According to the BCS theory, superconductivity arises from the formation of Cooper pairs; a pair of electrons that attract each other through an effective attractive interaction, resulting in a collective state known as the BCS state. The Cooper pair enable the flow of supercurrents without resistance. Furthermore, there are specific characteristic distances over which these moving pairs maintain coherence. The Ginzburg-Landau framework also predicts similar behavior, where the coherence length ξ is related to the penetration depth λ by the equation ξ=κλ. Here, κ is a dimensionless parameter known as the Ginzburg-Landau parameter, which typically ranges from 0<κ<1/\sqrt{2} for Type-I superconductors.

Experimental characterizations for several materials have been conducted. The coherence length typically ranges from hundreds to thousands of nanometers in most known superconducting materials. This range imposes practical limitations on applications that require extended stages or remote connections. For instance, such a limitation is a significant hurdle for the development of scaled quantum computers and distributed quantum signal processing. Furthermore, pioneering research studies are actively conducted to extend superconductivity to a high-temperature operation. Systems, devices, and/or methods described herein are for a propagation system for surface waves in the microwave frequency range, propagating along the interface between dielectric and superconducting layers. This new class of hybrid surface waves is composed of electromagnetic fields and supercurrent vortices. The electromagnetic fields occupy the dielectric side of the interface, extending significantly into the layer, similar to a bulk configuration.

In embodiments, the supercurrent vortices dominate on the superconductor side of the interface and penetrate to notably limited depths, measured by λ, which is only a few nanometers. In embodiments, the described superconductor-dielectric-superconductor heterostructures can support propagating modes of this microwave hybrid surface waves with spatial confinement far below the diffraction limit, such as down to just a few nanometers. Accordingly, the systems, devices, and/or methods described herein introduce applications in a manner akin to the emergence of traditional surface plasmon polaritons in the optical domain. For instance, employing this technique for constructing quantum devices and gates introduce a new modality with improved features.

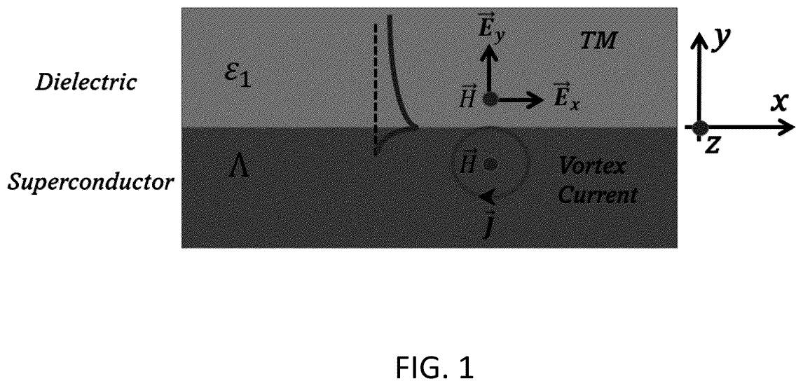

FIG. 1 describes a superconductor dielectric interface structure. The structure described in FIG. 1 is z independent. The superconductor is characterized by

$$Λ = \frac{{m}^{*}}{{{n}^{*} ( q )}^{*}} ,$$

and ϵ is the₁ dielectric relative permittivity. Here, m*, n* and q* are the mass, density, and charge of the super electrons. The electric fields on the superconductor side diminish, while superconducting currents are governed by Ampere's law and London's second law, yielding the magnetic Helmholtz equation, given by

$${∇}^{2} \vec{H} + \frac{1}{{λ}^{2}} \vec{H} = 0 , where λ = \sqrt{\frac{Λ}{{μ}_{0}}}$$

is the London penetration depth of the superconductor and po is the free space permeability. While the electric currents in the dielectric side of the interface vanish, the electric and magnetic fields are dictated by Ampere's and Faraday's laws. These two laws can be combined to form the known Helmholtz equation, which reads:

$${∇}^{2} \vec{H} + {ϵ}_{1} {k}_{0}^{2} \vec{H} = 0 , where {k}_{0} = \frac{ω}{c}$$

is the free space propagation constant.

In embodiments, there is a presence of a hybrid surface wave propagating along this interface between the superconductor layer and the dielectric layer. This hybrid surface wave consists of supercurrent vortices penetrating the superconducting side, and electromagnetic fields extending into the dielectric side. As detailed in the methods section and the supplementary material, the expressions of the TM (supercurrent and magnetic) fields in the superconductor side, for y<0, are given by:

$$\vec{H} = C {e}^{{K}_{2} y} {e}^{j β x} {e}^{- j ω t} {\vec{e}}_{z} + c . c . \qquad ( 1 )$$

$$\vec{J} = C ( {κ}_{2} {\vec{e}}_{x} - j β {\vec{e}}_{y} ) {e}^{{κ}_{2} y} {e}^{j β x} {e}^{- j ω t} + c . c . \qquad ( 2 )$$

The propagation constant can be found using Ampere's and London's second equations, reading

$$β = \sqrt{{κ}_{2}^{2} - \frac{{μ}_{0}}{Λ}} .$$

Here, κ₂ is the transverse decay rate, and C is a complex constant. In the dielectric side, in which y>0, the expressions of the TM electromagnetic fields are given by:

$$\vec{H} = A {e}^{- {κ}_{1} y} {e}^{j β x} {e}^{- j ω t} {\vec{e}}_{z} + c . c . \qquad ( 3 )$$

$$\vec{E} = A ( \frac{β}{ω {ε}_{0} {ε}_{1}} {\vec{e}}_{y} - j \frac{{κ}_{1}}{ω {ε}_{0} {ε}_{1}} {\vec{e}}_{x} ) {e}^{- {κ}_{1} y} {e}^{j β x} {e}^{- j ω t} + c . c . \qquad ( 4 )$$

In embodiments,

$$β = \sqrt{{κ}_{1}^{2} + {ε}_{1} {μ}_{1} {k}_{0}^{2}}$$

is the propagation constant, κ₁ is the traverse decay rate, A is a complex constant, j=\sqrt{−1} and c.c. stand for the complex conjugate.

In embodiments, the boundary conditions impose three relations. First, the continuity of the tangential magnetic fields at the interface implies A=C. Second, the continuity of the tangential electric field components, yielding κ₁=Λϵ₁χ₂κ₂. This relation is obtained by combining London's first equation with the supercurrent expression in equation (2) to calculate the induced tangential electric field in the superconductor. In embodiments, this induced tangential electric field is equated with the tangential electric field in the dielectric layer, equation (4), at y=0 (see Methods). Third, the equality of the propagation constants for y>0 and y<0. It then follows that the dispersion relation of the hybrid surface wave is given by:

$$β = \sqrt{\frac{{ε}_{1}^{2} {λ}^{2} {k}_{0}^{4} + {ε}_{1} {k}_{0}^{2}}{1 - {ε}_{1}^{2} {λ}^{4} {k}_{0}^{4}}} \qquad ( 5 )$$

where c is the speed of light in free space.

For typical dielectric and superconductor material parameters, the value of the propagation constant β calculated by equation (5) is nearly equal to the propagation constant in a bulk medium of the same dielectric material, i.e., \sqrt{ϵ₁k₀}. In embodiments, a significant portion of the surface wave resides within the dielectric side of the interface. For example, consider the air-aluminum superconductor interface, where the aluminum is operating at cryogenic temperatures and exhibiting superconductivity. For

$$\frac{ω}{2 π} = 10 GHz ,$$

the decay length in the dielectric material

$$\frac{1}{κ 2} = 16 nm .$$

while the surface wave penetration in the superconductor is as small

$$\frac{1}{κ 1} = 5 cm ,$$

Here β is almost identical to \sqrt{ϵ₁k₀}. Hence, despite the hybrid surface nature, the surface wave dispersion is very similar to a free space wave propagating in bulk dielectric media. However, various scenarios involving nano-confinement can be realized by considering a layered structure, as detailed in the following section.

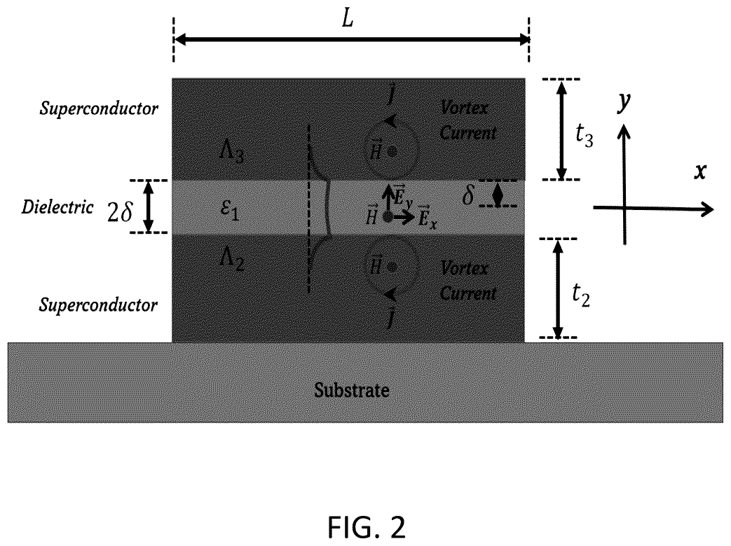

FIG. 2 is an example superconductor-dielectric interface to a layered medium composed of a superconductor-dielectric-superconductor (S-D-S) structure.

In embodiments, the depth of the superconductor layers “t_2” and “t_3” are in the range of tens to hundreds of nanometers (which is 7 to 10 times the penetration depth property of the chosen superconductor). A typical penetration depth of a superconductor (named Lambda in the work) is 10 to 20 nanometers.

In embodiments, the depth of the dielectric material, that is “2δ”, depends on the required properties, yet it is in the range of a few times the penetration depth “Lambda.” Accordingly, the total height of the structure (which is t_2+2δ+t_3) is the order of about 16 to 22 times Lambda, which is typically in the range of 160 to 200 nanometers. In embodiments, the width of the waveguide structure that is along the z-axis (which is not shown in FIG. 2) can be made the same as (or larger than) the height of the layers as required by the designer.

In embodiments, the length of the structure “L” is not restricted to any limit. It could be nanometers, millimeters, or even centimeters up to the design. The length limitation might come from the packaging or the required cryogenic refrigeration system. That is why this system can be used as a quantum device interconnector or even a transmission system. The structure also can be used to control the speed of the guided wave. Furthermore, the structure can be used as a building bone for quantum devices (such as Josephson Junctions) with unprecedented properties such as nano-compactness and probably long coherence time.

In embodiments, the three stacked layers are placed on a typical substrate similar to those used in typical electric chips (e.g., insulator, dielectric, plastic). Furthermore, the stack could be packed in typical packing material for any electronic chip. In embodiments, the superconductor layers of any type-I superconductor such as aluminum, lead, niobium-titanium, germanium-niobium, niobium nitride, etc., operate at cryogenic temperatures. In embodiments, the dielectric could be air, silica glass, ceramic, plastic, mica, etc.

In embodiments, the dielectric thickness is 2δ, while the superconductor layers are sufficiently thick to ensure that the supercurrent and magnetic fields decay significantly along the ±y directions. By expressing the fields in the three layers of the S-D-S structure in a manner similar to the expressions in equations (1) through (4), and applying the boundary conditions at the two interfaces, the governing dispersion relation for the propagating modes can be obtained, as in the following:

$${e}^{4 {κ}_{1} δ} = \frac{( {κ}_{3} {Λ}_{3} ω + \frac{{κ}_{1}}{{ωε}_{0} {ε}_{1}} )}{( {κ}_{3} {Λ}_{3} - \frac{{κ}_{1}}{{ωε}_{0} {ε}_{1}} )} \times \frac{( {κ}_{2} {Λ}_{2} ω + \frac{{κ}_{1}}{{ωε}_{0} {ε}_{1}} )}{( {κ}_{2} {Λ}_{2} - \frac{{κ}_{1}}{{ωε}_{0} {ε}_{1}} )} \qquad ( 6 )$$

For symmetric structure with Λ₃=Λ₂=Λ and κ₃=κ₂, the dispersion relation is given by

$${e}^{2 {κ}_{1} δ} = \pm \frac{( {κ}_{2} Λω + \frac{{κ}_{1}}{{ωε}_{0} {ε}_{1}} )}{( {κ}_{2} Λ - \frac{{κ}_{1}}{{ωε}_{0} {ε}_{1}} )} .$$

One possible solution to this solution is expressed as:

$$tanh ( {κ}_{1} δ ) = \frac{{κ}_{2} {ε}_{1} {λ}^{2} {k}_{0}^{2}}{{κ}_{1}} \qquad ( 7 )$$

In alternate embodiments, the expression in equation (7) can be simplified by considering two conditions: first, κ₁δ<<1, which can be achieved by using a thin dielectric layer; and second, κ₂λ≈1, which is naturally the case for superconductors given their small penetration depths. Under these conditions, the propagation constant can be approximated by:

$$β = {k}_{0} \sqrt{{ε}_{1} ( \frac{λ}{δ} + 1 )} \qquad ( 8 )$$

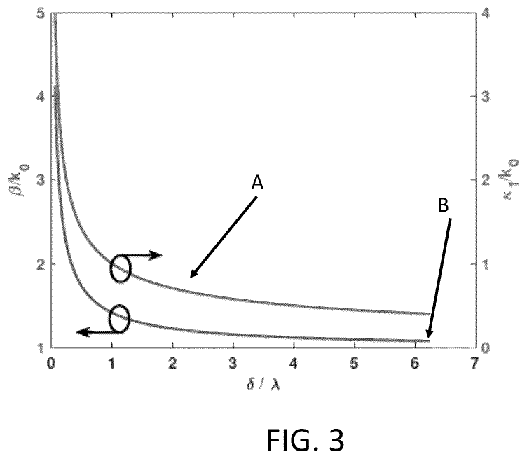

For example consider the Al-Air-Al superconductor-dielectric-superconductor layers. Using the expression in equation (8), the propagation constant β and the transverse decay coefficient κ₁ are graphically presented in FIG. 3 as functions of the insulating layer thickness δ. As shown in FIG. 3 the hybrid surface wave exhibits distinct properties when the dielectric thickness is comparable to the penetration depth of the superconductor material, demonstrating nano-confinement capabilities. However, for larger dielectric thicknesses, the propagation constant β approaches the propagation constant in bulk dielectric material, \sqrt{ϵ₁k₀}. To confirm the validity of the expression in equation (8), we calculated κ₂ from β and cross-checked the values with those in FIG. 3 to validate equation (7), achieving perfect agreement. As shown in FIG. 3, the curve described as feature A is the transverse decay factor (normalized to the free space propagation constant) quantifying the confinement of the electromagnetic field in the dielectric material. As shown in FIG. 3, feature B is the propagation constant of the propagating fields (normalized to the free space propagation constant).

To further describe the surface wave properties, the group velocity of the surface wave and the electromagnetic wave impedance is determined in the dielectric layer. The group velocity is defined by

$$v g = \frac{\partial ω}{\partial β} ,$$

reading:

$${v}_{g} = {v}_{0} \sqrt{\frac{λ}{δ} + 1} \qquad ( 9 )$$

$$where {v}_{0} = \frac{c}{\sqrt{{ϵ}_{1}}}$$

is the group velocity in the bulk dielectric material. The electromagnetic wave impedance in the dielectric layer is described by

$${Z}_{E M} = \frac{\vert \vec{E} \vert}{\vert \vec{H} \vert} .$$

Using the expression in equations (3) and (4), the electromagnetic wave impedance is given by:

$${Z}_{EM} = {\frac{β}{{ωε}_{0} {ε}_{1}} [ ( 1 - \frac{{k}_{0}^{2}}{{β}^{2}} ) ( 1 - \frac{tanh ( {δκ}_{1} )}{{δκ}_{1}} ) + 1 ]}^{\frac{1}{2}} \qquad ( 10 )$$

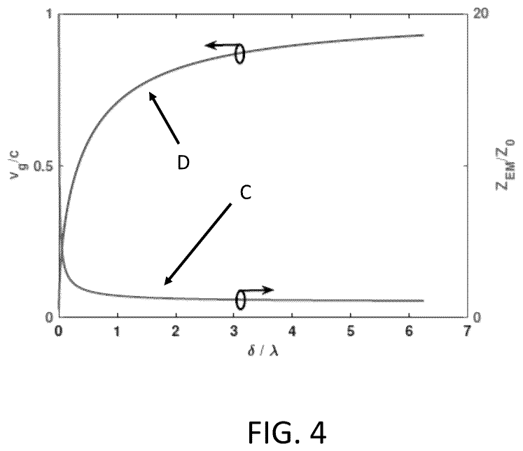

FIG. 4 graphically describes the group velocity and the electromagnetic wave impedance versus δ. Here,

$${Z}_{0} = \frac{377}{\sqrt{{ϵ}_{1}}}$$

is the electromagnetic wave impedance of the bulk dielectric. As shown in FIG. 4, feature C is the impedance of the electromagnetic fields in the dielectric media, constituting the ratio between the magnetic and electric fields. As shown in FIG. 4, feature D is the group velocity of the propagating fields

As shown in FIGS. 3 and 4, increasing dielectric thickness δ, well beyond the penetration depth λ, the surface wave tends to behave more like a typical electromagnetic wave propagating in a bulk dielectric medium. For instance, it can be seen from equations (8) to (10) that as δ approaches ∞, the propagation constant β, the group velocity v_{g}, and the wave impedance Z_{EM} become identical to the case of EM wave propagating in a bulk dielectric material with permittivity ϵ₁.

However, when δ is comparable to λ, the wave properties are distinct, and importantly, the confinement is significantly below the diffraction limit, which cannot be attained otherwise. Furthermore, it can be seen that as δ approaches 0, the group velocity vg approaches 0, and the impedance ZEM approaches ∞. Hence, the most interesting scenario occurs when the gap length δ is comparable to the penetration depth λ. For example, in addition to achieving nano-confinement, slow wave propagation with reduced group velocities can be engineered. It is important to note that this represents a significant breakthrough, opening the door to subwavelength control of microwave fields.

For a surface wave propagating along a dielectric-superconductor interface, the associated fields in different layers are governed by distinct physical principles. As illustrated in the schematic in FIG. 1, for y<0, the space is filled by the superconducting medium, where both supercurrent and magnetic fields can be physically present. The governing equations include Ampere's law and London's second law, given by:

$${∇}^{2} \vec{H} + {ε}_{1} {μ}_{1} {k}_{0}^{2} \vec{H} = 0 , where Λ = {μ}_{0} {λ}^{2} ,$$

and μ₀ is the free space permeability. Here, λ is the magnetic field penetration depth in the superconductor. In embodiments, the fields in the superconductor can be classified into a TM mode and a transverse supercurrent mode (TC). On the other hand, for y>0, the filling material is dielectric with electric and magnetic fields governed by Maxwell's equations:

$$∇ \times \vec{E} = - {μ}_{1} {μ}_{0} \frac{\partial \vec{H}}{\partial t} and$$

$$∇ \times \vec{H} = - {ε}_{1} {ε}_{0} \frac{\partial \vec{E}}{\partial t} .$$

Here, ϵ₁ and μ₁ are the relative permittivity and permeability, respectively. Combining Maxwell's equations yields the Helmholtz equation:

$${∇}^{2} \vec{H} + {ε}_{1} {μ}_{1} {k}_{0}^{2} \vec{H} = 0.$$

Similarly, the electromagnetic fields satisfying this equation can be categorized into a transverse magnetic mode (TM) and a transverse electric mode (TE). As shown in the next section, the propagating modes can be found by imposing the boundary conditions.

The propagating modes satisfy three boundary conditions include the continuity of the tangential magnetic fields, the continuity of the tangential electric fields, and having an identical propagation constant for all fields. As detailed in the supplementary, we found that only the T M modes in the dielectric and the superconductor layers can satisfy the boundary conditions and form a propagating surface wave. The T M mode in the superconductor encompasses a magnetic field in the z direction and supercurrent vortices that contain x and y components, as in equation (1) to equation (2). In the dielectric layer, the T M mode is comprised of a magnetic field along the z axis and electric fields along the y and x axes, as displayed in equation (3) equation (4). The first boundary conditions imply the equality of the z-directed magnetic fields on the two sides at y=0. Furthermore, the inductive electric field generated in the superconductor is governed by the first London's equation

$$\vec{E} = \frac{\partial }{\partial t} ( Λ \vec{J} ) {E}^{\to } .$$

Consequently, the second boundary condition is satisfied by having the tangential x-directed electric field in the dielectric layer and the tangential component of the inductive electric field generated by the supercurrent in the superconductor being identical at y=0. It then follows that by substituting the TM fields on both sides into the corresponding Helmholtz equations and equating the propagation constants, which satisfies the third boundary condition, the dispersion relation in equation (5) is derived (see Supplementary Material).

For multilayer structures, two configurations can be considered: Superconductor-Dielectric-Superconductor S-D-S and Dielectric-Superconductor-Dielectric (D-S-D). These two cases can be investigated by extending the field expressions in the three layers and applying the boundary conditions at the two interfaces. As elaborated in the Supplementary Material, the D-S-D configuration has weak confinement, with most of the associated fields of the surface wave occupying the insulator layers. Hence, the S-D-S scenario is the main focus of this work, as it shows unprecedented nano-confinement at microwave frequency ranges.

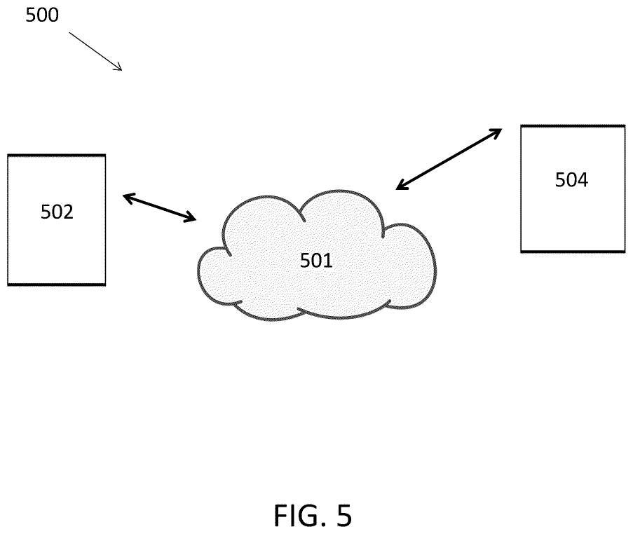

FIG. 5 is a diagram of example environment 500 in which systems, devices, and/or methods described herein may be implemented. FIG. 5 shows network 501, user device 502, user device 504, and antenna 506.

Network 501 may include a local area network (LAN), wide area network (WAN), a metropolitan network (MAN), a telephone network (e.g., the Public Switched Telephone Network (PSTN)), a Wireless Local Area Networking (WLAN), a WiFi, a hotspot, a Light fidelity (LiFi), a Worldwide Interoperability for Microware Access (WiMax), an ad hoc network, an intranet, the Internet, a satellite network, a GPS network, a fiber optic-based network, and/or combination of these or other types of networks. Additionally, or alternatively, network 500 may include a cellular network, a public land mobile network (PLMN), a second generation (2G) network, a third generation (3G) network, a fourth generation (4G) network, a fifth generation (5G) network, and/or another network.

In embodiments, network 501 may allow for devices describe any of the described figures to electronically communicate (e.g., using emails, electronic signals, URL links, web links, electronic bits, fiber optic signals, wireless signals, wired signals, etc.) with each other so as to send and receive various types of electronic communications.

User device 502 and/or 504 may include any computation or communications device that is capable of communicating with a network (e.g., network 2101). For example, user device 502 and/or user device 504 may include a radiotelephone, a personal communications system (PCS) terminal (e.g., that may combine a cellular radiotelephone with data processing and data communications capabilities), a personal digital assistant (PDA) (e.g., that can include a radiotelephone, a pager, Internet/intranet access, etc.), a smart phone, a desktop computer, a laptop computer, a tablet computer, a camera, a personal gaming system, a television, a set top box, a digital video recorder (DVR), a digital audio recorder (DUR), a digital watch, a digital glass, or another type of computation or communications device.

User device 502 and/or 504 may receive and/or display content. The content may include objects, data, images, audio, video, text, files, and/or links to files accessible via one or more networks. Content may include a media stream, which may refer to a stream of content that includes video content (e.g., a video stream), audio content (e.g., an audio stream), and/or textual content (e.g., a textual stream). In embodiments, an electronic application may use an electronic graphical user interface to display content and/or information via user device 502 and/or 504. User device 502 and/or 504 may have a touch screen and/or a keyboard that allows a user to electronically interact with an electronic application. In embodiments, a user may swipe, press, or touch user device 502 and/or 504 in such a manner that one or more electronic actions will be initiated by user device 502 and/or 504 via an electronic application. User device 502 and/or 504 may receive electronic information from antenna 506 and generate and display graphs such as those described in the figures above.

User device 502 and/or 504 may include a variety of applications, such as, for example, an e-mail application, a telephone application, a camera application, a video application, a multi-media application, a music player application, a visual voice mail application, a contacts application, a data organizer application, a calendar application, an instant messaging application, a texting application, a web browsing application, a blogging application, and/or other types of applications (e.g., a word processing application, a spreadsheet application, etc.). In embodiments, user device 502 and/or 504 may be used to generate graphs (such as those described in FIGS. 3 and 4) to model various features of the device described in FIG. 2.

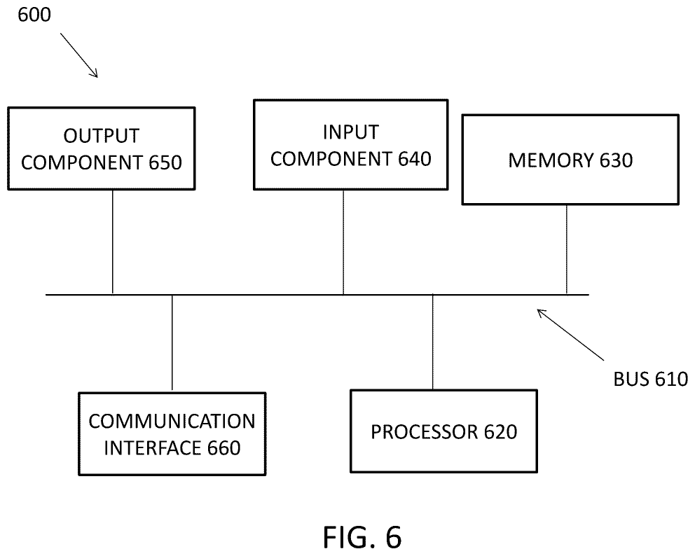

FIG. 6 is a diagram of example components of a device 600. Device 600 may correspond to user device 502, or user device 504. Alternatively, or additionally, user device 502 and user device 504 may include one or more devices 600 and/or one or more components of device 600.

As shown in FIG. 6, device 600 may include a bus 610, a processor 620, a memory 630, an input component 640, an output component 650, and a communications interface 660. In other implementations, device 600 may contain fewer components, additional components, different components, or differently arranged components than depicted in FIG. 6. Additionally, or alternatively, one or more components of device 600 may perform one or more tasks described as being performed by one or more other components of device 600.

Bus 610 may include a path that permits communications among the components of device 600. Processor 620 may include one or more processors, microprocessors, or processing logic (e.g., a field programmable gate array (FPGA) or an application specific integrated circuit (ASIC)) that interprets and executes instructions. Memory 630 may include any type of dynamic storage device that stores information and instructions, for execution by processor 620, and/or any type of non-volatile storage device that stores information for use by processor 620. Input component 640 may include a mechanism that permits a user to input information to device 600, such as a keyboard, a keypad, a button, a switch, voice command, etc. Output component 650 may include a mechanism that outputs information to the user, such as a display, a speaker, one or more light emitting diodes (LEDs), etc.

Communications interface 660 may include any transceiver-like mechanism that enables device 600 to communicate with other devices and/or systems. For example, communications interface 660 may include an Ethernet interface, an optical interface, a coaxial interface, a wireless interface, or the like.

In another implementation, communications interface 660 may include, for example, a transmitter that may convert baseband signals from processor 620 to radio frequency (RF) signals and/or a receiver that may convert RF signals to baseband signals. Alternatively, communications interface 660 may include a transceiver to perform functions of both a transmitter and a receiver of wireless communications (e.g., radio frequency, infrared, visual optics, etc.), wired communications (e.g., conductive wire, twisted pair cable, coaxial cable, transmission line, fiber optic cable, waveguide, etc.), or a combination of wireless and wired communications.

Communications interface 660 may connect to an antenna assembly (not shown in FIG. 6) for transmission and/or reception of the RF signals. The antenna assembly may include one or more antennas to transmit and/or receive RF signals over the air. The antenna assembly may, for example, receive RF signals from communications interface 660 and transmit the RF signals over the air, and receive RF signals over the air and provide the RF signals to communications interface 660. In one implementation, for example, communications interface 660 may communicate with network 501.

As will be described in detail below, device 600 may perform certain operations. Device 600 may perform these operations in response to processor 620 executing software instructions (e.g., computer program(s)) contained in a computer-readable medium, such as memory 630, a secondary storage device (e.g., hard disk, CD-ROM, etc.), or other forms of RAM or ROM. A computer-readable medium may be defined as a non-transitory memory device. A memory device may include space within a single physical memory device or spread across multiple physical memory devices. The software instructions may be read into memory 630 from another computer-readable medium or from another device. The software instructions contained in memory 630 may cause processor 620 to perform processes described herein. Alternatively, hardwired circuitry may be used in place of or in combination with software instructions to implement processes described herein. Thus, implementations described herein are not limited to any specific combination of hardware circuitry and software.

It will be apparent that example aspects, as described above, may be implemented in many different forms of software, firmware, and hardware in the implementations illustrated in the figures. The actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

While various actions are described as selecting, displaying, transferring, sending, receiving, generating, notifying, and storing, it will be understood that these example actions are occurring within an electronic computing and/or electronic networking environment and may require one or more computing devices, as described in FIG. 19, to complete such actions.

No element, act, or instruction used in the present application should be construed as critical or essential unless explicitly described as such. Also, as used herein, the article “a” is intended to include one or more items and may be used interchangeably with “one or more.” Where only one item is intended, the term “one” or similar language is used. Further, the phrase “based on” is intended to mean “based, at least in part, on” unless explicitly stated otherwise.

In the preceding specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A superconductor-dielectric-superconductor, comprising:
a first superconductor layer;
a dielectric layer; and
a second superconductor layer,
wherein surface waves, in a microwave frequency range, are configured to propagate along the interface between dielectric and superconducting layers,
wherein the surface waves are hybrid waves composed of electromagnetic fields and supercurrent vortices.

2. The superconductor-dielectric-superconductor of claim 1, wherein the surface waves are at microwave frequencies and are spatially below diffraction limit reaching nanometer confinements.

3. The superconductor-dielectric-superconductor of claim 1, wherein the superconductor-dielectric-superconductor slows down a propagating wave.

4. The superconductor-dielectric-superconductor of claim 1, wherein the superconductor dielectric-conductor is used for quantum interactions associated with comparability and controlled delay.
